(19) United States
(12) Patent Application Publication
(10) Pub. No.: US 2009/0250698 A1
(43) Pub. Date: Oct. 8, 2009

(54) FABRICATION MANAGEMENT SYSTEM

(76) Inventor: Nagaraj Savithri, Richardson, TX (US)

Correspondence Address: TEXAS INSTRUMENTS INCORPORATED, P O BOX 655474, M/S 3999, DALLAS, TX, 75265, US

(21) Appl. No.: 12/420,666

(22) Filed: Apr. 8, 2009

Related U.S. Application Data
(60) Provisional application No. 61/043,207, filed on Apr. 8, 2008.

(51) Int. Cl. H01L 23/00

(52) U.S. Cl. 257/48; 257/E23.002

(57) ABSTRACT

With the evolution of technology, there is a continual demand for enhanced speed, capacity and efficiency. A modular, chip testing system associated with a single chip on a wafer is described. This system includes a performance structure for measuring chip performance during a testing period; a power structure for measuring chip power during the testing period; an interconnect structure for measuring characteristics of interconnects within the chip during the testing period; a device structure for measuring characteristics of devices within the chip during the testing period; and a plurality of probe pads coupled to the performance structure, power structure, interconnect structure, and the device structure, wherein the plurality of probe pads receive signals during the testing period that enable the modular, chip testing system to measure characteristics of the interconnects, characteristics of the devices, chip power, and chip performance.

### CROSS REFERENCE TO RELATED APPLICATION(S)

The present application claims priority to jointly owned U.S. Provisional Application corresponding to application No. 61/043,207 entitled “Efficient Measurement of Performance and Power Variations in Advanced CMOS Technologies.” This provisional application was filed on Apr. 8, 2008 and has at least one common inventor.

### DESCRIPTION OF RELATED ART

With the evolution of technology, there is a continual demand for enhanced speed, capacity and efficiency. To meet these goals, great care must be taken during the fabrication of semiconductor devices. One area where there has been focus is on variations that may occur during the fabrication process. These variations may occur between fabrication facilities, lots, wafers, or dies. Regardless of the source, the resulting chip may be adversely impacted from these types of variations. Conventional solutions have attempted to resolve some of these issues by applying numerous structures around each die on a wafer. Some solutions apply as many as ten structures per die for assessing these variations. While the information acquired may be beneficial, using numerous separate structures consumes a sizable amount of real estate on each die and contributes to spatial variations. Consequently, there remain unmet needs relating to fabrication management systems.

### SUMMARY

The fabrication management system generally comprises a performance structure for measuring chip performance during a testing period; a power structure for measuring chip power during the testing period; an interconnect structure for measuring characteristics of interconnects within the chip during the testing period; a device structure for measuring characteristics of devices within the chip during the testing period; and a plurality of probe pads coupled to the performance structure, power structure, interconnect structure, and the device structure, wherein the plurality of probe pads receive signals during the testing period that enable the modular, chip testing system to measure characteristics of the interconnects, characteristics of the devices, chip power, and chip performance.

### BRIEF DESCRIPTION OF THE DRAWINGS

The fabrication management system may be better understood with reference to the following figures. The components within the figures are not necessarily to scale, emphasis instead being placed upon clearly illustrating the principles of the invention. Moreover, in the figures, like reference numerals designate corresponding parts or blocks throughout the different views.

FIG. 1 is an environmental drawing illustrating an electronic device and associated fabrication process management system.

FIG. 2A is planar view illustrating multiple dies on a wafer with corresponding fabrication management systems.

FIG. 2B is planar view illustrating an alternative implementation of FIG. 2A.

FIG. 3 is a planar view illustrating components within the fabrication management system.

FIG. 4A is a planar view illustrating path delay associated with the fabrication management system.

FIGS. 4B-4C are planar views illustrating representations of the path delay of FIG. 4A.

FIGS. 5A-5B are tables with sample values in accordance with one implementation of the fabrication management system.

FIGS. 5C is a combined graph illustrating characteristics of the fabrication management system.

FIGS. 6A-6C are graphs illustrating comparisons of actual and simulated results for performance, voltage trends, and power measurements for one implementation of the fabrication management system.

FIG. 7 is a flow chart associated with implementing the fabrication management system.

While the fabrication management system is susceptible to various modifications and alternative forms, specific embodiments have been shown by way of example in the drawings and subsequently are described in detail. It should be understood, however, that the description herein of specific embodiments is not intended to limit the motion conversion system to the particular forms disclosed. In contrast, the intention is to cover all modifications, equivalents, and alternatives falling within the spirit and scope of the motion conversion as defined by this document.

### DETAILED DESCRIPTION OF EMBODIMENTS

As used in the specification and the appended claim(s), the singular forms “a,” “an” and “the” include plural referents unless the context clearly dictates otherwise. Similarly, “optional” or “optionally” means that the subsequently described event or circumstance may or may not occur, and that the description includes instances where the event or circumstance occurs and instances where it does not.

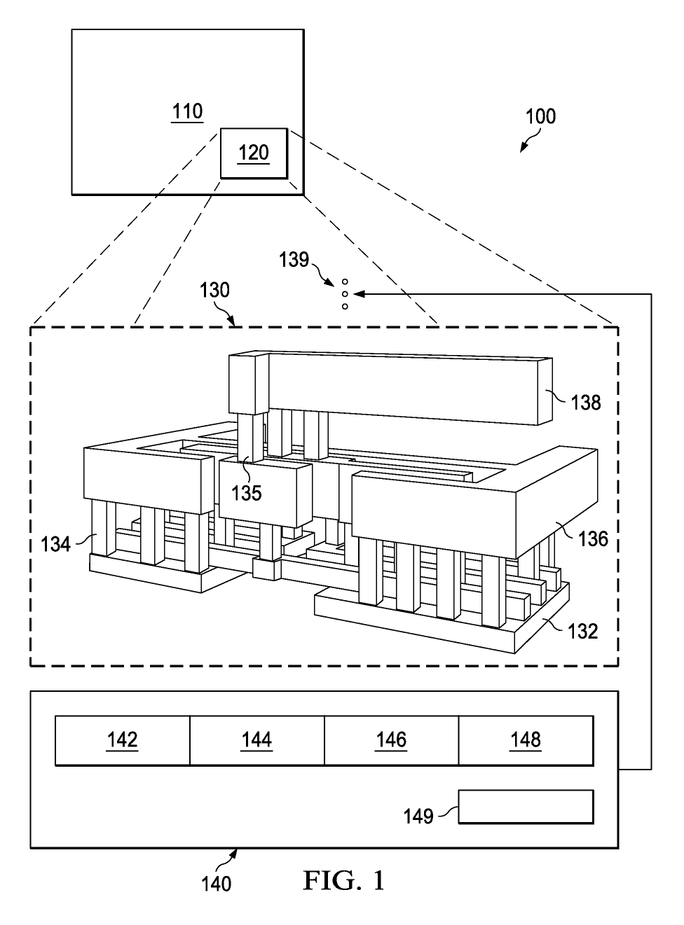

Turning now to FIG. 1, this is an environmental drawing 100 illustrating an electronic device 110 that includes an integrated circuit (IC) 120 and associated fabrication process management system 140. The electronic device 110 may be one of various types of electronic devices including a central processing unit, processor for a cellular telephone, a modem, a controller, a digital signal processor, and the like. In an alternative implementation, the electronic device may be a product that includes one of these types of devices. For example, the electronic device 100 may be a computer that includes a central processing unit, digital signal processor, controller or modem. Alternatively, the electronic device 110 may be a cellular telephone that includes a processor for the cellular telephone as described above. For any of these types, electronic device 110 includes an integrated circuit (IC) 120. While the electronic device 110 is shown as including on the IC 120, one skilled in the art will appreciate that this is merely a representative illustration. In fact, the electronic device 110 may often include numerous integrated circuits (ICs) with varying dimensions and functions.

As clearly seen in FIG. 1, an exploded view of the IC 120 illustrates a portion of a chip 130 for a single die and an associated fabrication management system 140. The chip 130 includes a diffusion layer 132, vias 134, vias 135, first metal layer 136, and second metal layer 138. The diffusion layer 132 may include any one of various types of mechanisms, such as boron diffusion, silicon germanium and the like. The vias 134, 135 allow connection between the layers and may be composed of any one of various types of materials such as copper, tungsten and the like. Similarly, the first metal layer 136 and the second metal layer 138 may be composed of any one of various types of materials such as copper, aluminum, and the like. In an alternative implementation, the first metal layer 136 and the second metal layer 138 may be composed using different materials. Alternatively, these metal layers may be composed of the same material with different concentrations. As indicated by the dots 139, the chip 130 includes additional layers. In one implementation, this die may include a total of five additional metal layers with vias in between each metal layer. Alternatively, the die may include 0, 3, 8, 10, or some other suitable number of additional layers.

Returning to FIG. 1, there is a single fabrication management system 140 associated with the chip 130. Alternatively, the fabrication management system 140 may be referred to as a scribe module, chip testing system, or the like. This fabrication management system includes a performance structure 142 for measuring chip performance and a device structure 144 for measuring characteristics of devices within the chip 130. In addition, the fabrication management system 140 also includes a power structure 146 for measuring chip power and an interconnect structure 148 for measuring characteristics of interconnects within the chip during the testing period. As a result, the fabrication management system 140 can assess during the fabrication process how the partially constructed chip is actually functioning relative to targeted goals by analyzing its power, performance, interconnects and devices. The structure of this unique fabrication management system 140 enables parallel assessment of the actual chip behavior. In other words, the performance measurements, device measurements, power measurements, and interconnect measurements associated with structures 142-148 may be done in parallel. Moreover, this fabrication management system includes a control device 149 that allows alterations to be made in the subsequent fabrication process to compensate for identified variations. In an alternative implementation, the fabrication management system 140 may include a memory performance structure for measuring the performance of memory elements.

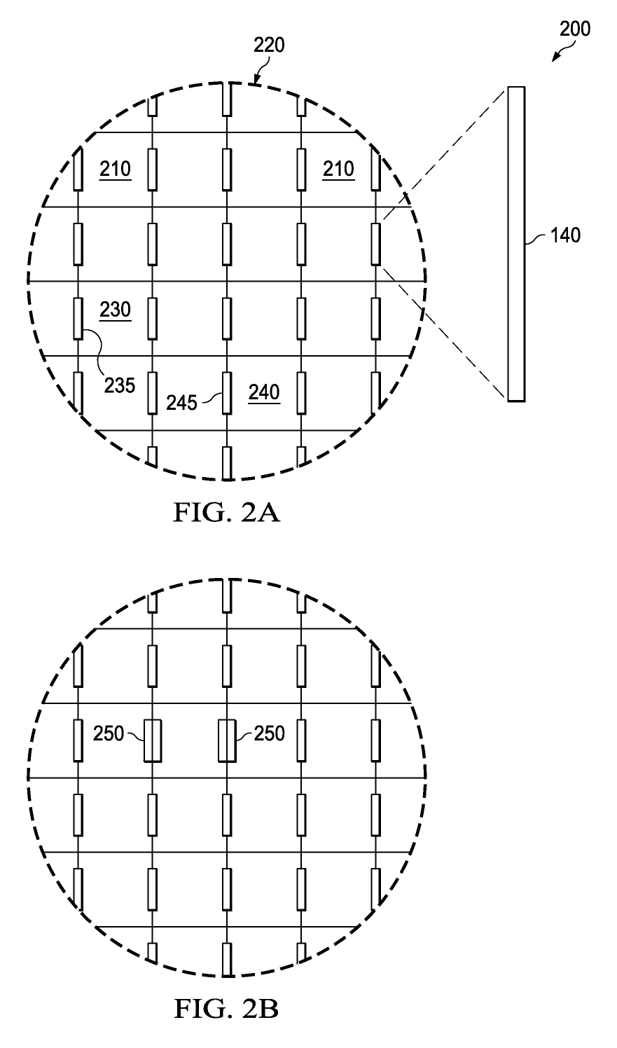

As mentioned above, there is one fabrication management system 140 associated with each chip resulting from a wafer die. FIG. 2A is a planar view illustrating multiple dies 210 on a wafer 220 with corresponding fabrication management systems 140. For each die in the figure, there is only one fabrication management system associated with it. For example, die 230 has an associated fabrication management system 235 and die 240 has an associated fabrication management system 245. By only using a single modular testing system like the fabrication management systems 140, 235, 245 instead of conventional solutions, there is a considerable savings on wafer real estate and a reduction in spatial variations that may adversely impact measurements. In an alternative implementation shown in FIG. 2B, there may a reduced number (e.g., two) of fabrication management systems used for a single chip as shown at reference numeral 250. Other implementations may result from using a three or four fabrication management systems.

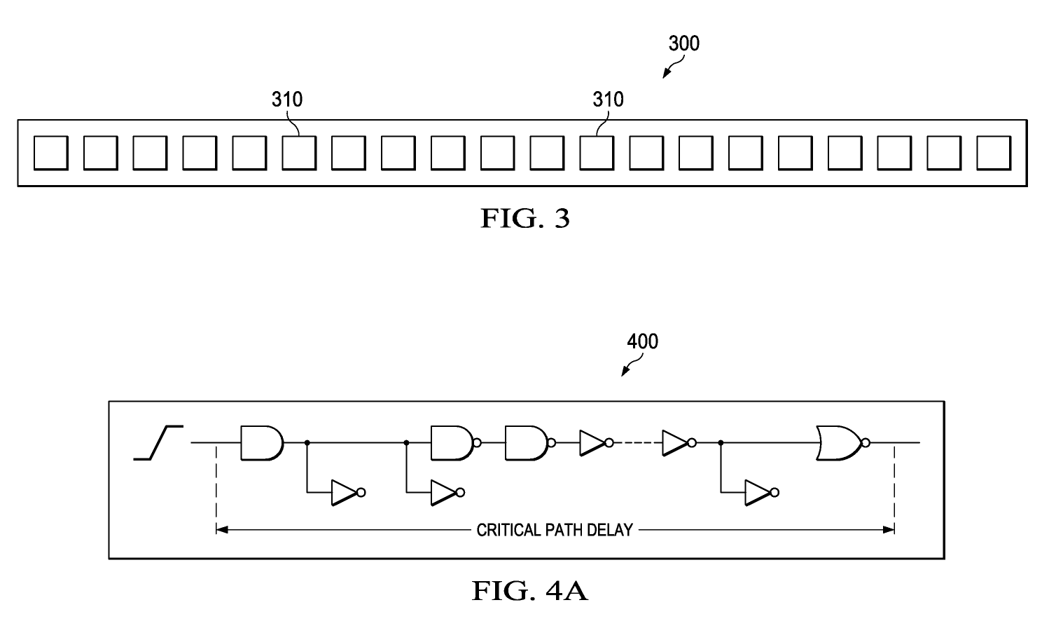

FIGS. 3A-3B are planar views illustrating various implementations of the components within the fabrication management system 140. More specifically, FIG. 3A illustrates one implementation 300 of the fabrication management system 140 that includes twenty probe pads with dimensions of approximately 50 μm by 2000 μm. The dimensions of the probe pads may be approximately 1 μm, 50 μm, or the like. In an alternative implementation, the fabrication management system 140 may include eighteen pads, twenty four pads, thirty six pads, or some other suitable number of pads. Similarly, the dimensions may be calculated if the spacing between the probe pads varies from approximately 30 μm to approximately 50 μm, the number of pads is known, and the dimension of each pad is known (e.g., approximately 50 μm.). Since the fabrication management system 140 includes a performance structure 142, device structure 144, power structure 146, and interconnect structure 148, the pads may be equally divided among these structures. Alternatively, some structures may have an assigned percentage of the pad allocation, while the remaining structures are equally divided. Thus, there are various types of systems that may be used for selecting pads associated with a given structure.

In the implementation 300, the probe pads 310 are spaced apart, which enable insertion of a testing structure between them. There is normally one pad associated with each testing structure, though other implementations are possible. In addition, the space between the probe pads 310 may be constant in the entire fabrication management system 140. Alternatively, the dimensions between the probe pads 310 may vary. A testing structure as used herein generally refers to one or more circuits that perform a specific measurement function. For example, the performance structure 142 is at least one circuit that can be used in measuring the operating speed, frequency, or the like for the chip 130. Similarly, the device structure 144 may be used in measuring attributes of devices within this chip. These attributes may include transistor turn-on current, transistor turn-off current, transistor threshold voltage, transistor switching current, or some other suitable attribute. The power structure 146 enables measuring the leakage power when the chip 130 is static, dynamic power when chip 130 is switching, or the like. Finally, the interconnect structure 148 facilitates measuring attributes for interconnects within the chip 130. Examples of these interconnects may include the interconnect resistance, interconnect capacitance and the like. The fabrication management system 140 may make these measurements within a permissible operating voltage range (e.g., approximately 0.7 volts to approximately 1.2 volts) and permissible temperature range (.e.g., approximately −40° C. to approximately 125° C.).

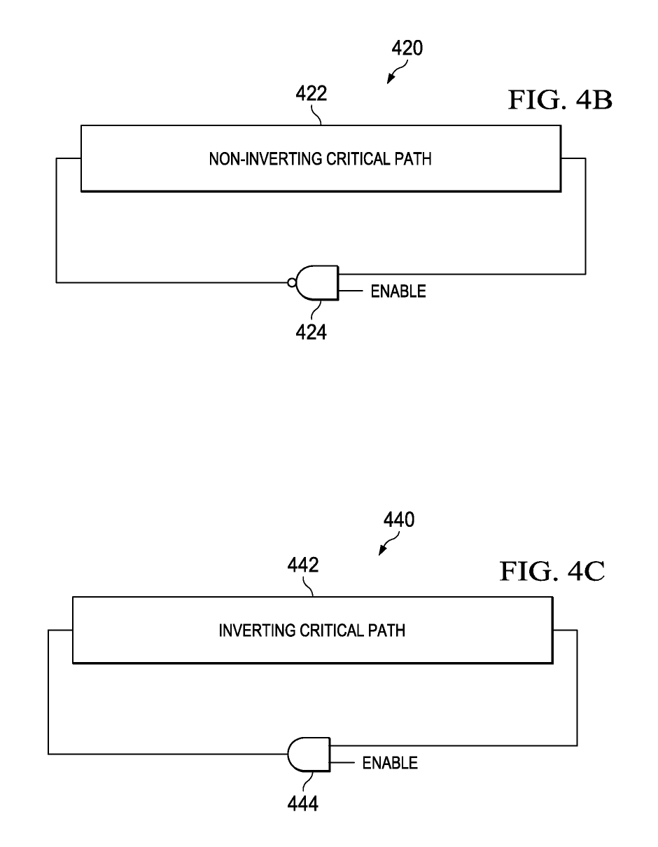

Simulation techniques, such as modeling, may be used in producing the above-mentioned testing structures. This modeling may be done using any one of various types of modeling programs, such as physical design, timing analysis, or the like. In modeling the chip 130, one may assess what the minimum, or critical, path delays are associated with a given type of structure. Generally, a critical path delay occurs between flip-flops or memories and becomes critical if it is limiting speed of the product. For example, if there are ten paths with the following speeds: path1 with 500 MHz, path2 with 475 MHz and path10 with 400 MHz. Path10 becomes the critical path because it is slowest speed or limiting speed of that product. Turning now to FIG. 4A, it is a planar view 400 illustrating a path delay associated with the fabrication management system 140. This is one of many ways that a critical path delay may be represented using an AND gate, NAND gates, inverters, and a NOR gate. An alternative implementation may utilize structured data paths. Additional information relating to this may include memory access circuits, or the like.

FIGS. 4B-4C are planar views illustrating representations of the path delay 400. In FIG. 4B, the path delay 400 may be configured as a ring oscillator 420 within the interconnect structure 148. In this configuration, the ring oscillator 420 includes a non-inverting critical path 422 and a two input NAND gate 424 with an enable. Alternatively, the path delay 400 may be configured as a ring oscillator 440 as illustrated in FIG. 4C. In contrast, the ring oscillator 440 includes an inverting critical path 442 and a 2-input AND gate 444. While FIGS. 4B-4C demonstrate configurations for the testing structure using ring oscillators, an alternative implementation may result from using default delay type configurations instead of ring oscillators. In other words, delay fault circuit techniques may be used. Moreover, configurations for the performance structure 142, device structure 144, and power structure 146 may use ring oscillators, default delay configurations, or some other suitable configuration. Additional information relating to this may include memory access testing circuits.

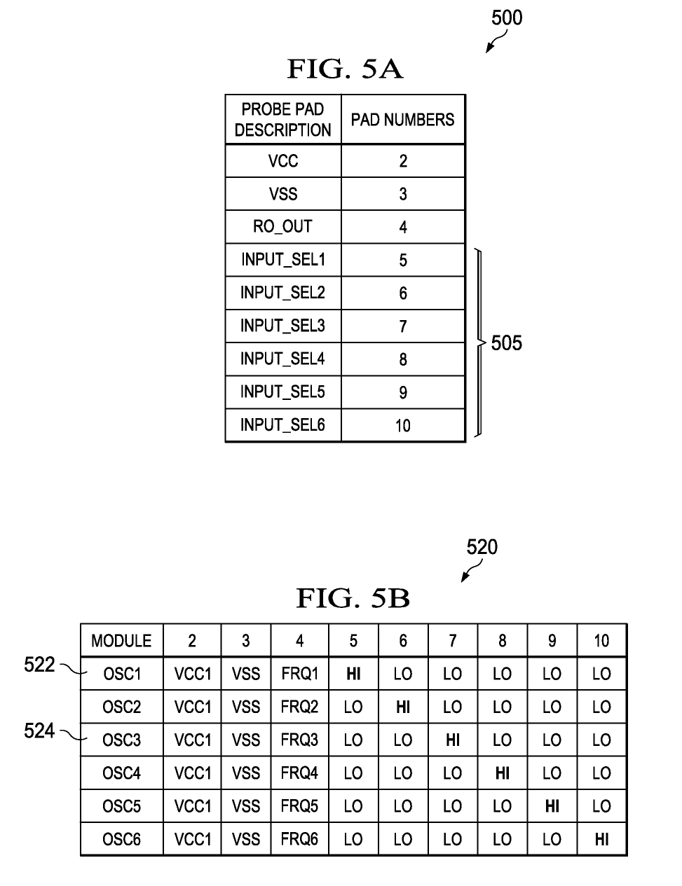

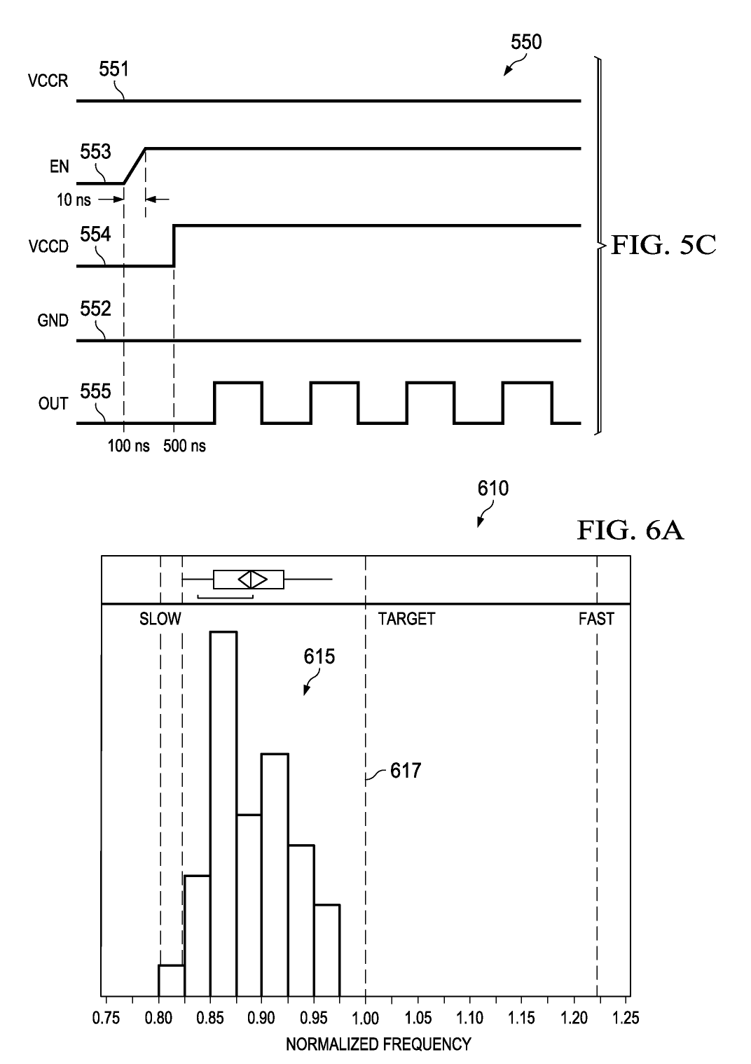

FIGS. 5A-5B are tables with sample values in accordance with one implementation of the fabrication management system 140. In this example, this fabrication management system includes ten probe pads. Pad 2 and Pad 3 are respectively assigned to the positive supply voltage and the negative supply voltage. Pad 4 receives an output signal from a ring oscillator that has been selected. The group 505 depicts pads that receive input signals from a tester for selecting a particular ring oscillator. Examples of this testing machine may be a Keithley machine or some other suitable tester. Within the group 505, there are six individual input signals, which may be input signals for six ring oscillators. As described with reference to FIGS. 4B-4C, the ring oscillators include an enable, or input, signal.

FIG. 5B illustrates a table 520 of how changing the values of some of these input signals can correspondingly select a particular ring oscillator. For example, applying a high input signal to pad 5 selects ring oscillator 1 on row 522 for testing, which produces a corresponding output signal labeled FRQ1. Similarly, applying a high input to pad 8 selects ring oscillator 4 on row 524 for testing, which produces a corresponding output signal labeled FRQ4. If the interconnect structure 148 includes these six ring oscillators shown in table 520, selecting a particular oscillator may give information about interconnects. For example, ring oscillator 4 on row 524 may correspond to interconnects 135 between the first metal layer 136 and the second metal layer 138 (see FIG. 1).

FIGS. 5C is a combined graph 550 illustrating characteristics of the fabrication management system 140. As illustrated, the supply voltage V_{cc} on line 551 stays high, while the supply voltage Vₛₛ (GND) on line 552 stays low. In this instance the ring oscillator input signal, or enable, is on line 553 and transitions from low to high in approximately 10 ns. Alternatively, the input signal may transition from low to high in 8 ns, 13 ns, or the like. Even after the input signal transitions, another 390 ns pass before the supply voltage on line 554 in the divider circuit transitions from low to high. One skilled in the art will appreciate that this divider circuit may be located adjacent to the ring oscillator and is operative for dividing high frequency oscillation to lower frequency for ease of measurement. After the divider circuit transitions from low to high, the output signal (FRQ4) on line 555 transitions from low to high after approximately 500 ns. The fabrication management system 140 may then analyze attributes of this output signal and ascertain information about vias 135. For example, if circuit performance is slower, one of possible cause is increases in resistance to capacitance ratio (R/C). Interconnect measurement structures help in ascertaining these.

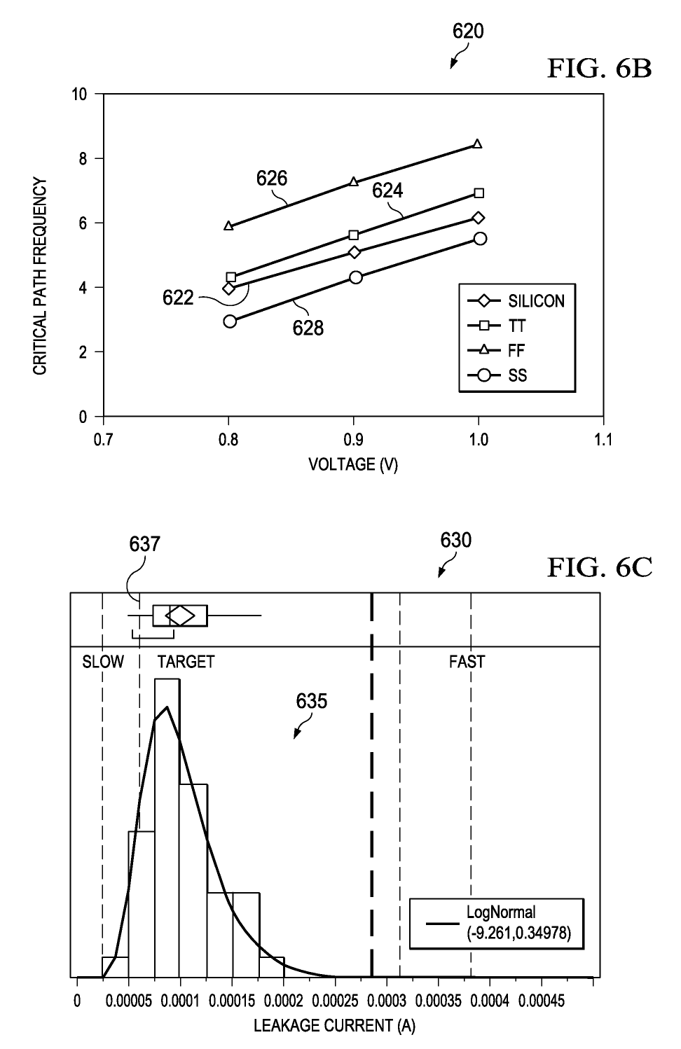

FIGS. 6A-6C are graphs illustrating comparisons of actual and simulated results for performance, voltage trends, and power measurements for one implementation of the fabrication management system. In FIG. 6A, the graph 610 illustrates the comparison between actual performance for the chip 130 and simulated performance. The actual performance data at reference numeral 615 is in histogram format showing the average performance is slower than the targeted performance shown as dashed line 617. FIG. 6B is a graph 620 illustrating comparison of actual voltage trends with simulated voltage trends. In this graph, simulated results are shown on line 622 and labeled as Silicon in the legend. The actual results of typical NMOS and typical PMOS (TT) are shown on line 624. In contrast, the actual results for fast NMOS and fast PMOS are shown on line 626, while the actual results for slow NMOS and slow PMOS are shown on line 628. Therefore, one can conclude that the voltage trends between actual results and simulated results are similar. This information can be used to determine voltage scaling aspects in performance optimization. Finally, the graph 630 in FIG. 6C illustrates a power comparison between actual and simulated measurements. The actual power data at reference numeral 635 is in histogram format showing the average performance aligned closely with the targeted performance shown as dashed line 637. This information can be used to assess leakage power correlation.

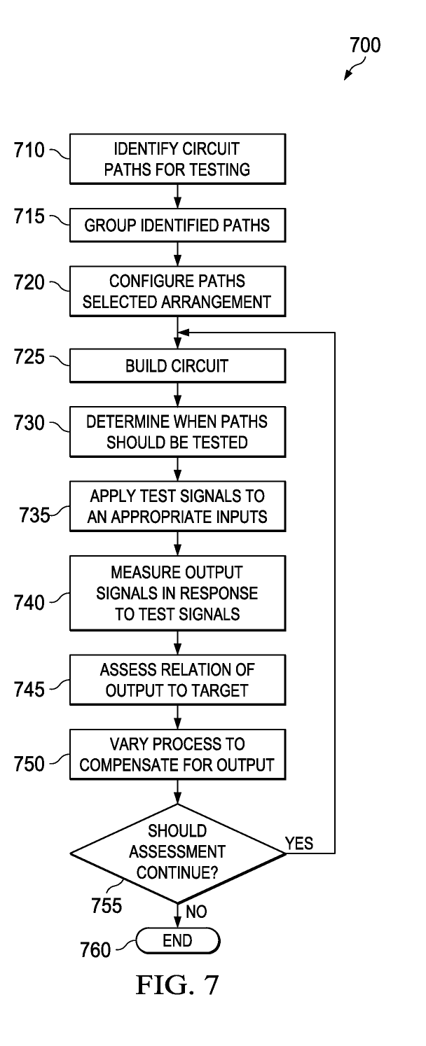

FIG. 7 is a flow chart associated with implementing the fabrication management system 140. The fabrication management technique of flow chart 700 begins at block 710 by identifying circuit paths for testing. Typically, this identification may be completed during the fabrication of the fabrication management system 140 by identifying areas of the completed circuit that have attributes that may impact circuit performance, circuit power, device measurement, and interconnect measurements. For example, this block may include identifying various minimal path delays.

Block 710 may be followed by block 715, though an alternative embodiment may omit block 715. In this block, identified paths are grouped together. Block 720 follows block 725. In block 720, paths are configured in a certain arrangement (e.g., a ring oscillator). Once the paths are configured, block 725 follows and the circuit is built according to the configuration. In an alternative implementation, block 720 and block 725 may be combined.

Block 725 is followed by block 730, which determines when the identified paths should be tested. This determination may be based on user input or a calculation. For example, there may be a calculation of the total number of metal layers, flip-flops, or memories and the most beneficial times for testing in light of those numbers. If there are seven metal layers, testing may be completed after metal layer three and metal layer five. An alternative implementation may result from moving block 725 earlier in the technique. For example, block 730 may be completed contemporaneously with either one of the blocks 710-720.

Block 735 follows block 730. In block 735, test signals are applied to appropriate inputs. The application of these signals may begin a testing period. For example, an input signal may be applied to a ring oscillator in the interconnect structure 148. Because the measurements associated with the performance structure 142, device structure 144, power structure 146, and interconnect structure may be done in parallel as mentioned above, there may be other input signals applied to other structures. Block 735 is followed by block 740, which measures output signals in response to the applied input signals. The receipt of output signals may end the testing period. One skilled in the art will appreciate that alternative implementations may result when some or all of the structure measurements are not completed in parallel.

Block 740 is followed by block 745 where the relation of the outputs to targets are assessed. While shown as a separate block, an alternative implementation may be done where block 745 is included in block 740. Even still, another embodiment may result when block 745 is completed contemporaneously with block 740.

Block 750 follows block 740. In block 750, the fabrication process is varied to compensate for the measured outputs. This compensation may be completed by exporting a variation signal to another device that controls the fabrication process. Varying the process may involve finishing a certain number of wafers with the current settings and then changing subsequent wafers. Alternatively, it may involve intermediately changing additional layers in the currently tested wafer as a way of compensating for measurements in the completed layers. Finally, block 750 is followed by block 755 where there is an assessment of whether the technique should continue. Factors influencing the outcome of this assessment may include passage of time, addition of subsequent layers or some other suitable factor. If the outcome of this assessment is yes, block 725 follows block 755. Otherwise, block 760 follows block 755 and the flow ends.

The fabrication management system 140 is a unique and beneficial system in meeting unmet needs of conventional systems. This system saves test time by enabling all measurements of transistor, interconnect, circuit performance, and circuit power to be done in parallel. In addition, it reduces electrical noise and minimizes noise errors by substantially reducing or eliminating multiple testing modules for a single chip on the die. Moreover, the fabrication management system 140 is applicable to alternative implementations that may result from performing circuit performance and circuit power measurements on the following: datapath circuits, central processing unit core circuits, register files, memory access circuits, multiple gate lengths, and multiple threshold voltage transistors.

While various embodiments of the fabrication management system have been described, it may be apparent to those of ordinary skill in the art that many more embodiments and implementations are possible that are within the scope of this system. Although certain aspects of the fabrication management system may be described in relation to specific techniques or structures, the teachings and principles of the present system are not limited solely to such examples. All such modifications are intended to be included within the scope of this disclosure and the present motion conversion system and protected by the following claim(s).

1. A modular, chip testing system associated with a single chip on a wafer, comprising:
a performance structure for measuring chip performance during a testing period;
a power structure for measuring chip power during the testing period;
an interconnect structure for measuring characteristics of interconnects within the chip during the testing period;
a device structure for measuring characteristics of devices within the chip during the testing period; and
a plurality of probe pads coupled to the performance structure, power structure, interconnect structure, and the device structure,
wherein the plurality of probe pads receive signals during the testing period that enable the modular, chip testing system to measure characteristics of the interconnects, characteristics of the devices, chip power, and chip performance.

2. The chip testing system of claim 1, wherein the testing period occurs before processing in the chip is complete.

3. The chip testing system of claim 1, wherein measurements made during the testing period are selected from the group consisting of: transistor on-current, transistor off-current, threshold voltage, switching current, interconnect resistance, interconnect capacitances, operating speed, leakage power and dynamic power.

4. The testing system of claim 1, wherein at least one of the performance structure, power structure, device structure, and interconnect structure comprises a ring oscillator representing a delay associated with a critical path in the chip.
